(19) United States
(12) Patent Application Publication
(10) Pub. No.: US 2020/0139905 A1
(43) Pub. Date: May 7, 2020

(54) CABLE CONNECTION STRUCTURE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Hirokazu KOMORI, Mie (JP); Hiroki HIRAI, Mie (JP); Makoto HIGASHIKOZONO, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 16/630,629

(22) PCT Filed: Jul. 4, 2018
(86) PCT No.: PCT/JP2018/025302

§ 371 Date: Jan. 13, 2020

(30) Foreign Application Priority Data
Jul. 20, 2017 (JP) 2017-140573

(51) Int. Cl. B60R 16/023; H05K 9/00; B60R 16/03; B60T 13/74; B60T 8/17; B60T 17/00

(52) U.S. Cl. CPC B60R 16/023; H05K 9/0064; B60T 17/00; B60T 13/74; B60T 8/17; B60R 16/03

(57) ABSTRACT

A cable connection structure includes a cable including a power cable including a power line and a power shield line, a signal cable including a signal line and a signal shield line, a control unit including a control-side ground, and a controlled unit that includes a controlled-side ground, receives supply of power from the control unit, and exchanges the electric signals with the control unit. The power shield line and the signal shield line are connected to the control-side ground and the controlled-side ground. At least one of the power cable and the signal cable includes an earth line that connects the control-side ground and the controlled-side ground to each other.

### TECHNICAL FIELD

A technique disclosed in the present specification relates to a cable connection structure, and in particular to a technique for suppressing transmission of noise from a power line to a signal line in a cable including the power line and the signal line.

### BACKGROUND ART

Conventionally, for example, a technique disclosed in Patent Document 1 is known as a technique for suppressing transmission of noise from a power line to a signal line as described above. Patent Document 1 discloses a technique that suppresses noise in a cable used in an electric brake device of an automobile. In Patent Document 1, specifically, a technique is disclosed in which generation of noise in the signal line by the power line is suppressed, by constituting the power line by a twisted pair wire, constituting the signal line by a coaxial cable including a shield wire, and passing a DC current through the power line.

### CITATION LIST

### Patent Documents

Patent Document 1: JP 2008-179354A

### SUMMARY OF INVENTION

### Technical Problem

However, a DC brushless motor is often used in an electric brake device due to user-friendly control, and in such a case, high frequency noise may be generated by the power line to which an AC voltage is applied. For this reason, a technique for suppressing the influence on the signal line of high frequency noise that is generated by the power line is desired.

Furthermore, there are cases in which body earthing directly is difficult with a device that is provided outside of the vehicle body, such as a motor drive device used in an electric brake device. Accordingly, in such cases, a ground on the motor drive device side and a ground on the body side are connected via the power line and the shield line of the signal line, and a braided wire is used as the shield line in some cases. However, in the electric brake device, vibration stress may act on the braided wire due to vibration generated during driving of the vehicle, and the braided wire may be disconnected by the vibration stress. If the braided wire is disconnected, the shielding effect of the shield line will decrease and the function of the ground connection line will be lost. For this reason, a cable connection structure that can improve the reliability of ground connection and suppress the influence on a signal line of high frequency noise generated by a power line has been desired.

A technique disclosed in the present specification was made in view of the above circumstances, and provides a cable connection structure that can improve the reliability of ground connection and suppress the influence on a signal line of high frequency noise generated by a power line.

### Solution to Problem

A cable connection structure disclosed in the present specification is a cable connection structure that connects a control unit and a controlled unit to each other, the cable connection structure including a cable including a power cable including a power line that supplies power and a power shield line that is formed by a braided wire and shields the power line, and a signal cable including a signal line that transmits electric signals and a signal shield line that is formed by a braided wire and shields the signal line, a control unit that is connected to one end of the power line and one end of the signal line, includes a control-side ground, and controls supply of the power and transmission of the electric signals, and a controlled unit that is connected to another end of the power line and another end of the signal line, includes a controlled-side ground, receives supply of power from the control unit, and exchanges the electric signals with the control unit, and the power shield line is connected to the control-side ground and the controlled-side ground, the signal shield line is connected to the control-side ground and the controlled-side ground, and at least one of the power cable and the signal cable includes an earth line that connects the control-side ground and the controlled-side ground to each other.

According to this configuration, in addition to the power shield line and the signal shield line, an earth line is provided to at least one of the power cable and the signal cable, as a ground connection line. For this reason, even in cases such as where the ground connection function between the control unit and controlled unit may be lost due to disconnection of both the power shield line and the signal shield line, for example, the ground connection function can be maintained by the earth line. Furthermore, due to the earth line, it is possible to suppress the influence on the signal line of high frequency noise generated by the power line. For this reason, with the cable connection structure according to this configuration, it is possible to improve the reliability of ground connection and suppress the influence on the signal line of high frequency noise generated by the power line.

In the above-described cable connection structure, both the power cable and the signal cable may include the earth line.

With this configuration, both the power cable and the signal cable include the earth line. Accordingly, the reliability of ground connection can be further improved, and the influence on the signal line of high frequency noise generated by the power line can be further suppressed.

Furthermore, in the above-described cable connection structure, the earth line may be formed by an insulated wire, and arranged inside the power shield line and the signal shield line.

With this configuration, since the earth line is arranged inside the shield line, the earth line is protected by the shield line. In this manner, the reliability of the earth line is improved, and consequently, the reliability of the cable connection structure can be improved.

Furthermore, in the above-described cable connection structure, a configuration is also possible in which the controlled-side ground includes a power ground to which the other end of the power line and the earth line are connected, and a signal ground to which the other end of the signal line and the earth line are connected, and the power ground and the signal ground are individually provided to be separated from each other.

With this configuration, the power ground and the signal ground are individually provided to be separated from each other in the controlled unit. For this reason, compared to a case in which the power ground and the signal ground are provided in common, it is possible to suppress a case in which high frequency noise generated by the power line affects the signal line via the ground on the controlled unit-side.

Furthermore, in the above-described cable connection structure, a configuration is also possible in which the control unit is an electric brake control unit that is provided inside a vehicle body of a vehicle, and controls an electric brake actuator of the vehicle, and the controlled unit is the electric brake actuator provided outside the vehicle body of the vehicle.

With this configuration, the cable connection structure is applied to a cable that connects an electric brake control unit provided inside the vehicle body and an electric brake actuator provided outside the vehicle body to each other. In this case, vibration stress acts on the braided shield line of the cable due to vibration during driving of the vehicle, and the braided shield line may be disconnected due to the vibration stress. However, even if the braided shield line is disconnected, the earth line can ensure the function of the ground connection line, and the influence on the signal line of high frequency noise generated by the power line can be suppressed.

### Advantageous Effects of Invention

According to the cable connection structure disclosed in the present specification, it is possible to improve the reliability of ground connection and suppress the influence on a signal line of high frequency noise generated by a power line.

### BRIEF DESCRIPTION OF DRAWINGS

FIG. 1 is a schematic block diagram showing a cable connection structure according to an embodiment.

FIG. 2 is a diagram showing a basic configuration of a simulation test of the cable connection structure.

FIG. 3 is a diagram showing an exemplary configuration of the simulation test.

FIG. 4 is a diagram showing another exemplary configuration of the simulation test.

FIG. 5 is a diagram showing another exemplary configuration of the simulation test.

FIG. 6 is a diagram showing another exemplary configuration of the simulation test.

FIG. 7 is a diagram showing another exemplary configuration of the simulation test.

FIG. 8 is a graph showing results of the simulation test.

### DESCRIPTION OF EMBODIMENTS

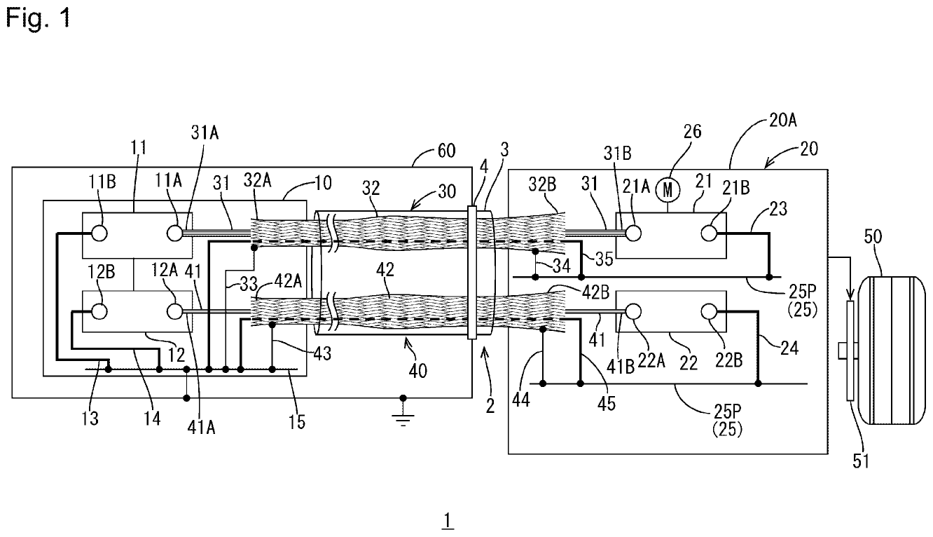

Hereinafter, a cable connection structure 1 according to an embodiment will be described with reference to FIGS. 1 to 8. The cable connection structure 1 of the present embodiment is a connection structure of a cable 2 that connects an electric brake control unit 10 mounted in an automobile and an electric brake actuator 20 to each other. In other words, the present embodiment illustrates an example in which the cable connection structure 1 is applied to an electric brake of an automobile, that is, a so-called EMB (Electro-Mechanical Brake).

### 1. Configuration of Cable Connection Structure

As shown in FIG. 1, the cable connection structure 1 includes the cable 2, the electric brake control unit 10, and the electric brake actuator 20. Here, the electric brake control unit 10 is an example of a “control unit”. Also, the electric brake actuator 20 is an example of a “controlled unit”. Hereinafter, the electric brake actuator 20 is merely referred to as “the actuator 20”.

The cable 2 includes a power cable 30, a signal cable 40, and a sheath 3. The cable 2 is fixed to a vehicle body 60 with a prescribed grommet 4.

The power cable 30 includes a power line 31, a power shield line 32, and a power earth line (corresponds to earth line) 35. Power is supplied from the electric brake control unit 10 to the actuator 20 through the power line 31.

The power shield line 32 is constituted by a braided wire, and one end 32A thereof is connected to a ground 15 (hereinafter, referred to as “control-side ground”) of the electric brake control unit 10. Another end 32B of the power shield line 32 is connected to a power ground 25P that is an actuator ground 25 (corresponds to controlled-side ground), and covers and shields the power line 31.

The power line 31 is constituted by, for example, three insulated core wires. In other words, in the present embodiment, three-phase power is supplied to the actuator 20 through the power line 31. Note that the configuration is not limited thereto, and, for example, the power line 31 may be constituted by a single core wire, and DC power may be supplied to the actuator 20.

As shown in FIG. 1, the power earth line 35 is arranged inside the power shield line 32, and connects the control-side ground 15 and the power ground 25P (an example of the controlled-side ground) to each other. The power earth line 35 is a coated wire (insulated wire), and is constituted by, for example, a single core wire having a cross sectional area of approximately 2.5 mm² (sq.) and an insulating coating that covers the core wire.

On the other hand, the signal cable 40 includes a signal line 41, a signal shield line 42, and a signal earth line 45 (corresponds to earth line). The signal line 41 transmits electric signals between the electric brake control unit 10 and the actuator 20. The electric signals include, for example, various types of control signals to be sent to the actuator 20, various types of sensor signals to be received from the actuator 20, and the like.

Similarly to the power shield line 32, the signal shield line 42 is constituted by a braided wire, and one end 42A thereof is connected to the control-side ground 15. Another end 42B of the signal shield line 42 is connected to a signal ground 25S that is the actuator ground 25, and covers and shields the signal line 41. The signal line 41 is constituted by, for example, twelve core wires, and the core wires are covered with an insulating coating (not shown) and insulated.

The signal earth line 45 is provided inside the signal shield line 42 and connects the control-side ground 15 and the signal ground (an example of the controlled-side ground) 25S to each other. Similarly to the power earth line 35, the signal earth line 45 is a coated wire (insulated wire), and is constituted by a single core wire having a cross sectional area of approximately 2.5 mm² (sq.) and an insulating coating that covers the core wire, for example.

As described above, in the present embodiment, the earth lines (35 and 45) are arranged inside the shield lines (32 and 42), respectively, and thus the earth lines (35 and 45) are protected by the shield lines (32 and 42). In this manner, the reliability of the earth lines (35, 45) is improved, and consequently, the reliability of the cable connection structure 1 can be improved.

The sheath 3 is constituted by an insulative tape, for example, and covers the power cable 30 and the signal cable 40 by winding with gaps between windings, or with half-overlapping windings.

Note that there is no limitation to the earth lines (35 and 45) being arranged inside the shield lines (32 and 42), respectively. For example, the earth lines (35 and 45) may be arranged between the shield lines (32 and 42) and the sheath 3, respectively.

The electric brake control unit 10 is provided inside the vehicle body 60. The electric brake control unit 10 is connected to one end 31A of the power line and one end 41A of the signal line, includes the control-side ground 15, and controls power supply to the electric brake actuator 20 and transmission of the electric signals. Additionally, the electric brake control unit 10 includes an inverter (not shown) that generates three-phase power.

Specifically, the electric brake control unit 10 includes, for example, a power control unit 11, a signal control unit 12, and the control-side ground 15. The power control unit 11 includes an output terminal 11A and a ground terminal 11B. The output terminal 11A is connected to the one end 31A of the power line, and the ground terminal 11B is connected to the control-side ground 15 via a ground wiring 13, for example. On the other hand, the signal control unit 12 includes an output terminal 12A and a ground terminal 12B. The output terminal 12A is connected to the one end 41A of the signal line, and the ground terminal 12B is connected to the control-side ground 15 via a ground wiring 14, for example.

Furthermore, in the electric brake control unit 10, the one end 32A of the power shield line 32 is connected to the control-side ground 15 via a ground wiring 33, and the one end 42A of the signal shield line 42 is connected to the control-side ground 15 via a ground wiring 43. The control-side ground 15 is connected to the vehicle body 60. In other words, the control-side ground 15 is connected to a body earth. Note that any configuration of the ground wirings (13, 14, 33, and 43) can be employed, such as any length, for example.

On the other hand, the actuator 20 is provided outside the vehicle body 60. The actuator 20 is connected to another end 31B of the power line and another end 41B of the signal line, exchanges electric signals with the electric brake control unit 10 and electrically acts on a disc brake 51 of a tire 50.

Specifically, the actuator 20 includes, for example, a motor control unit 21, a communication unit 22, an actuator ground 25, a motor 26, and an accommodation box 20A. As shown in FIG. 1, the actuator ground 25 is separated into the power ground 25P of a power system and the signal ground 25S of a signal system. Note that the configuration of the actuator ground 25 is not limited thereto, and the actuator ground 25 may be formed integrally rather than being separated into the power ground 25P and the signal ground 25S. Additionally, the actuator 20 includes various types of sensors, gears, a brake pad, a caliper, and the like (not shown).

The motor control unit 21 includes an input terminal 21A and a ground terminal 21B. The input terminal 21A is connected to the other end 31B of the power line, and the ground terminal 21B is connected to the power ground 25P via the ground wiring 23, for example. On the other hand, the communication unit 22 includes an input terminal 22A and a ground terminal 22B. The input terminal 22A is connected to the other end 41B of the signal line, and the ground terminal 22B is connected to the signal ground 25S via a ground wiring 24, for example.

The motor 26 is connected to the motor control unit 21, and causes the brake pad (not shown) to act on the disc brake 51 by rotational force. In the present embodiment, the motor 26 is a DC brushless motor, for example. The motor control unit 21 receives a three-phase driving voltage from the electric brake control unit 10, and supplies three-phase driving voltage to the motor 26. Note that the configuration is not limited thereto, and the motor 26 may also be a DC brushless motor with built-in inverter. At this time, a DC voltage is supplied from the electric brake control unit 10. Furthermore, the motor 26 is not limited to a DC brushless motor.

Furthermore, in the actuator 20, the other end 32B of the power shield line 32 is connected to the power ground 25P via a ground wiring 34, for example, and the other end 42B of the signal shield line 42 is connected to the signal ground 25S via a ground wiring 44. Note that any configuration of the ground wirings (23, 24, 34, and 44) can be employed, such as any length, for example.

In this way, in the present embodiment, the cable connection structure 1 is applied to a configuration in which the ground 25 of the actuator 20 (controlled unit) is placed in a state apart from the ground 15 of the electric brake control unit 10 (control unit), and the connection between the control-side ground 15 and the actuator ground 25 is carried out by the shield lines (32 and 42). At this time, in the present embodiment, the power ground 25P of the actuator 20 is connected to the control-side ground 15 of the electric brake control unit 10 via the power shield line 32 and the power earth line 35. Similarly, the signal ground 25S of the actuator 20 is connected to the control-side ground 15 via the signal shield line 42 and the signal earth line 45.

Additionally, the effect of suppressing noise transmission from the power line 31 to the signal line 41 in the present embodiment was confirmed through simulation described hereinafter.

2. Simulation Test of Noise Transmission from Power Line to Signal Line

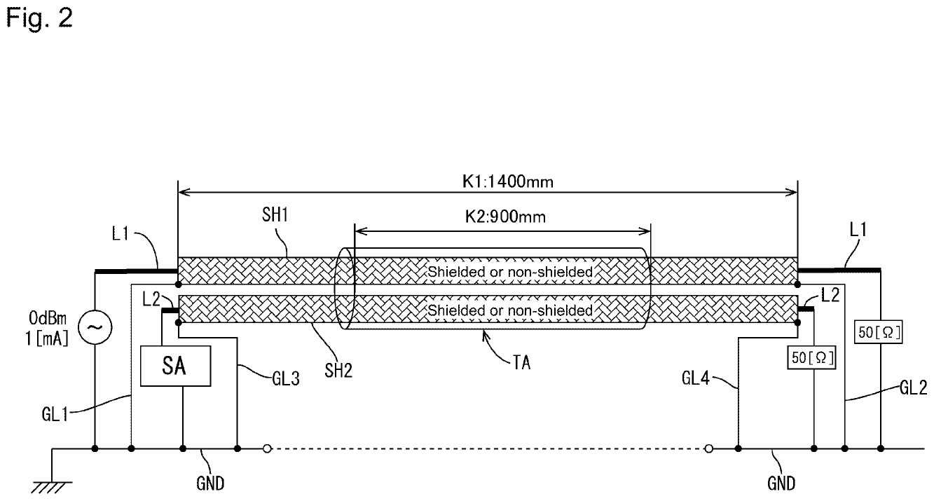

Next, a simulation test of noise transmission from the power line to the signal line will be described with reference to FIGS. 2 to 8.

As shown in FIG. 2, the basic configuration of the simulation test was as follows: in the case where shield lines SH1 and SH2 were provided to a power line L1 and a signal line L2, respectively, a length K1 of the shield lines SH1 and SH2 was 1400 mm; a length K2 of the sheath tape TA that covers the power line L1 and the signal line L2, that is, the length for which the power line L1 and the signal line L2 run parallel to each other, was 900 mm. Ground wirings GL1 and GL2 were provided at the ends of the shield line SH1, and ground wirings GL3 and GL4 were provided at the ends of the shield line SH2. A ground GND was constituted by a copper plate.

The power line L1 was a single line having a cross sectional area of approximately 2.5 mm² (sq.), and the signal line L2 was a single line having a cross sectional area of 1.25 mm², and both of the lines L1 and L2 were coated by insulating coating parts (not shown). Furthermore, the power line L1 and the signal line L2 were integrated by a sheath tape TA. Note that any configuration of the ground wirings (GL1 to GL4) can be employed, such as any length, for example. Additionally, coated copper wires having a cross sectional area of approximately 2.5 mm² (sq.) were used for earth lines EL1 and EL2.

Additionally, a test signal of 0 dBm (1 mW) power was input to one end (control unit side) of the power line L1, and the other ends (actuator side) of the power line L1 and the signal line L2 were terminated by 50Ω resistors. At this time, a spectrum analyzer SA was connected to the control unit side of the signal line L2 and the power induced in the signal line L2 by crosstalk was measured. Note that the test signals were sine waves, and were scanned at a frequency between approximately 10 KHz and 1 GHz. Additionally, in simulation modes M1 and M5, the ground GND on the control unit side and the ground GND on the actuator side were electrically connected and integrated by a prescribed connection line or the like.

### 2-1. Simulation Mode M1

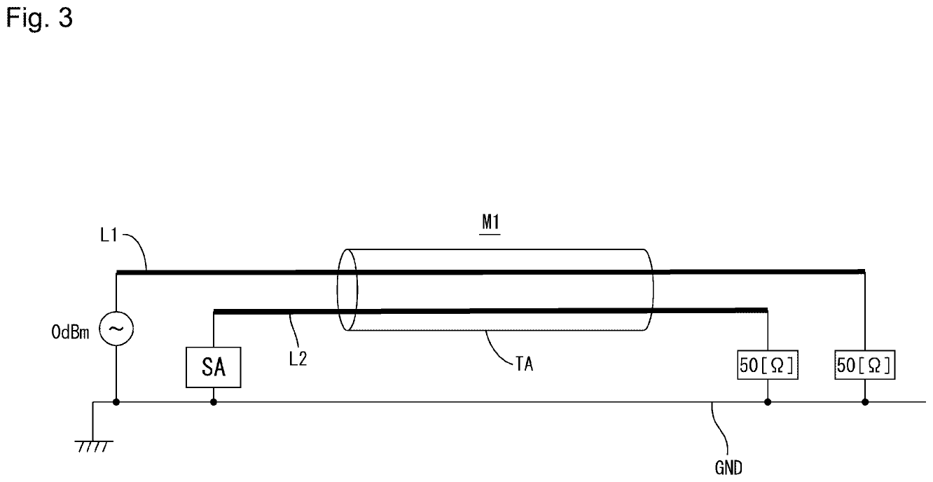

In the simulation mode M1, simulation was performed with a configuration in which the shield lines SH1 and SH2 were not provided and the power line L1 and the signal line L2 were covered only with the sheath tape TA, as shown in FIG. 3.

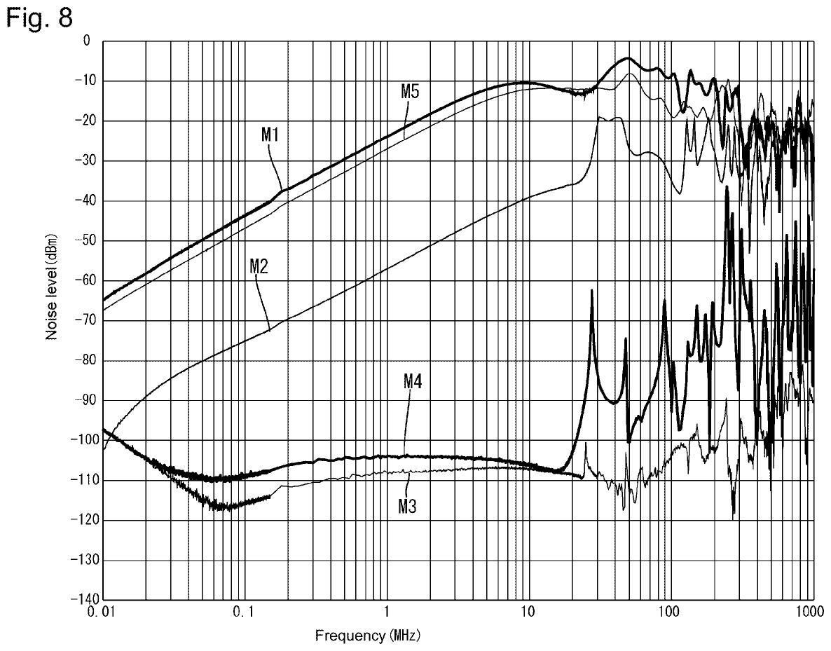

The result of the simulation mode M1 is indicated by a curved line M1 in FIG. 8. In this case, it is shown that the level of noise induced in the signal line L2 is the highest of the simulations.

### 2-2. Simulation Mode M2

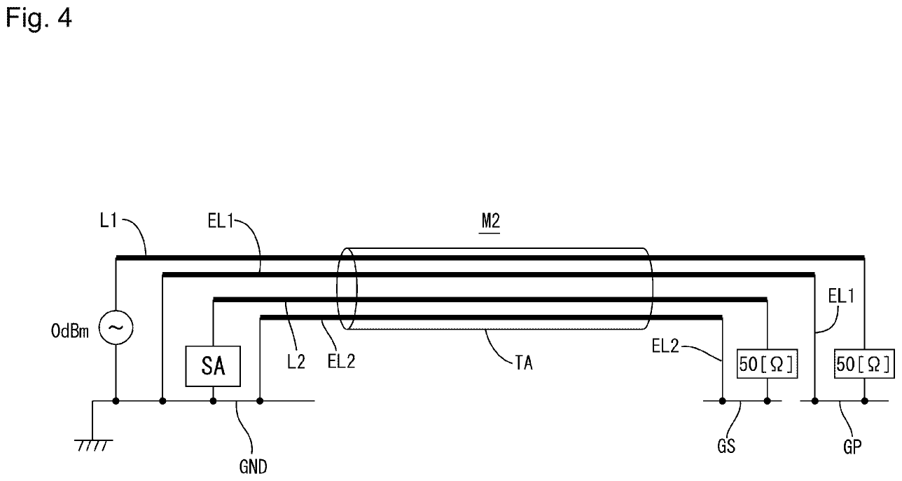

In the simulation mode M2, the shield lines SH1 and SH2 were not provided, and the earth line EL1 was provided in proximity to the power line L1, and the earth line EL2 was provided in proximity to the signal line L2, as shown in FIG. 4. Simulation was performed with a configuration in which ends on one side of the earth lines EL1 and EL2 were connected to the ground GND on the control unit side, and the ends on the other side of the earth lines EL1 and EL2 were connected to the ground on the actuator side. Note that a power ground GP and a signal ground GS on the actuator side were not connected on the actuator side, but were connected on the control unit side via the earth lines E1 and E2, and via the ground GND. Note that “being proximity to” also includes being in contact with. In other words, the earth line EL1 may be provided in contact with the power line L1, and the earth line EL2 may be provided in contact with the signal line L2.

The result of the simulation mode M2 is indicated by a curved line M2 in FIG. 8. In this case, a noise level reduction effect was achieved in a frequency domain of 1 MHz to 100 MHz, compared to the simulation mode M1. In other words, a noise level reduction effect due to the earth lines EL1 and EL2 in a case where the shield lines SH1 and SH2 were not provided was confirmed.

### 2-3. Simulation Mode M3

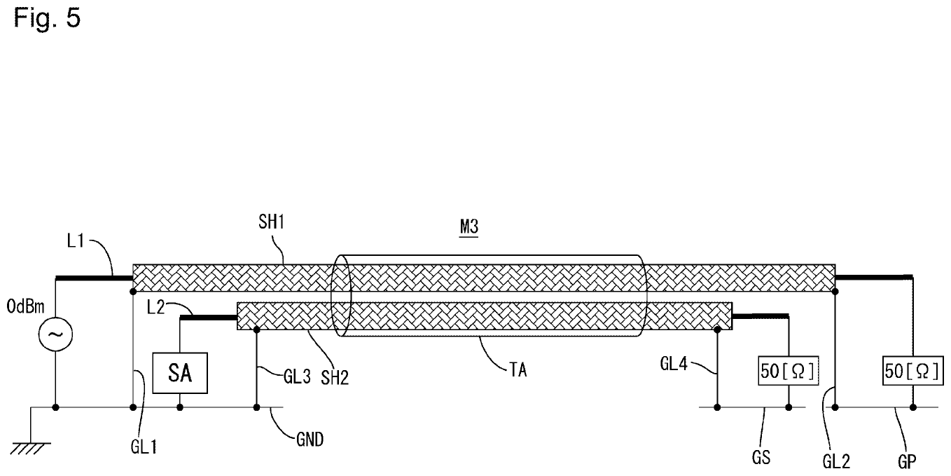

In the simulation mode M3, only the shield lines SH1 and SH2 were provided, as shown in FIG. 5. Simulation was performed with a configuration in which the both ends of the shield lines SH1 and SH2 were connected to the ground on both sides, and the power ground GP and the signal ground GS were not connected on the actuator side. In this configuration, the power ground GP and the signal ground GS were provided common (integrated) to the ground GND on the control unit side by the shield lines SH1 and SH2.

The result of the simulation mode M3 is indicated by a curved line M3 in FIG. 8. In this case, it was confirmed that the level of noise induced in the signal line L2 was reduced the most of the simulations across substantially the whole frequency range.

### 2-4. Simulation Mode M4

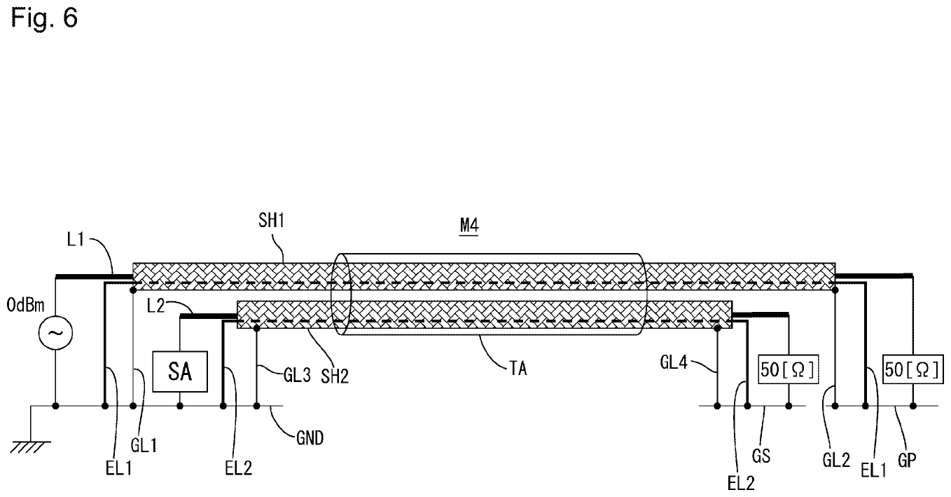

In the simulation mode M4, the shield lines SH1 and SH2 and the earth lines EL1 and EL2 were provided as shown in FIG. 6. Simulation was performed with a configuration in which both ends of the shield lines SH1 and SH2 and the earth lines EL1 and EL2 were connected to the ground on both sides, and the power ground GP and the signal ground GS were not connected on the actuator side. This configuration is a configuration in which the power ground GP and the signal ground GS are provided in common (integrated) to the ground GND on the control unit side through the shield lines SH1 and SH2 and the earth lines EL1 and EL2, and corresponds to the present embodiment.

The result of the simulation mode M4 is indicated by a curved line M4 in FIG. 8. In this case, it was confirmed that the level of noise induced in the signal line L2 was reduced to substantially the same level as the simulation mode M3 in a frequency domain up to substantially 20 MHz. In other words, the earth line EL1 was provided in proximity to the power line L1, and the power line L1 and the earth line EL1 were shielded by the shield line SH1. In addition, the earth line EL2 was provided in proximity to the signal line L2, and the signal line L2 and the earth line EL2 were shielded by the shield line SH2. In this configuration, the power ground GP and the signal ground GS were not connected, in other words, were provided individually, on the actuator side.

Note that it was confirmed that in a frequency domain of greater than or equal to 20 MHz, the effect of noise level reduction is small compared to that of the simulation mode M3.

### 2-5. Simulation Mode M5

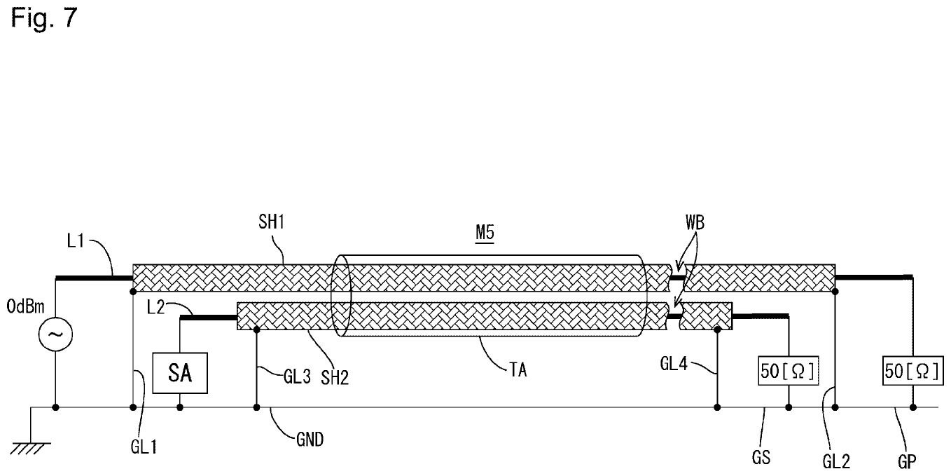

In the simulation mode M5, simulation was performed on the assumption that disconnection WB has occurred in the shield lines SH1 and SH2 in the case where the control-side ground and the actuator-side ground are connected to each other in the simulation mode M3, as shown in FIG. 7.

The result of the simulation mode M5 is indicated by the curved line M5 in FIG. 8. In this case, as shown in FIG. 8, it was confirmed that the result is substantially close to that of the simulation mode M1. In other words, if the disconnection WB occurs due to the shield lines SH1 and SH2, the reduction effect of the noise level caused by the shield lines SH1 and SH2 can be mostly obtained. Note that, from the results of the simulation mode M1 and the simulation mode M2, it is conceivable that, in the simulation mode M5, if the earth lines EL1 and EL2 are provided (corresponds to the present embodiment), a noise level reduction effect by the earth lines EL1 and EL2 close to the result of the simulation mode M2 can be obtained.

In other words, from the results of above simulations, it was confirmed that, in the present embodiment, even if disconnection occurs in the shield lines (32 and 42), the connection between the control-side ground 15 and the actuator ground 25 is ensured by the earth lines (35 and 45), and predetermined noise level reduction effects can be obtained. 3. Effects of Present Embodiment

The cable connection structure 1 according to the present embodiment can be applied to a configuration in which the ground 25 of the actuator 20 (controlled unit) is placed in a state apart from the ground 15 of the electric brake control unit 10 (control unit), and the control-side ground 15 and the actuator ground 25 are connected to each other by the shield lines (32 and 42).

In this case, according to the cable connection structure 1 of the present embodiment, the power earth line 35 is provided to the power cable 30, and the signal earth line 45 is provided to the signal cable 40 as the ground connection lines that connect the control-side ground 15 and the actuator ground 25 to each other, aside from the power shield line 32 and the signal shield line 42. For this reason, even if disconnection occurs in both the power shield line 32 and the signal shield line 42, and the ground connection function of the electric brake control unit 10 (control unit) and the electric brake actuator 20 (controlled unit) is lost, the ground connection function will be maintained by the earth lines (35 and 45). In addition, the earth lines (35 and 45) can suppress the influence on the signal line 41 of high frequency noise generated by the power line 31. For this reason, with the cable connection structure 1 according to the present embodiment, it is possible to improve the reliability of ground connection and to suppress the influence on the signal line 41 of high frequency noise generated by the power line 31.

Also, in the present embodiment, the actuator ground (controlled-side ground) 25 includes the power ground 25P and the signal ground 25S, and the power ground and the signal ground are individually provided to be separated from each other. Accordingly, compared to the case where the power ground and the signal ground are integrated, it is possible to suppress a situation where high frequency noise generated by the power line 31 affects the signal line 41 via the controlled-side ground.

Furthermore, in the present embodiment, the cable connection structure 1 is applied to the cables (30 and 40) that connect the electric brake control unit 10 provided inside the vehicle body and the electric brake actuator 20 provided outside of the vehicle body to each other. In this case, vibration stress acts on the braided shield lines (32 and 42) of the cable (30 and 40) due to vibrations during driving of the vehicle, and the braided shield lines (32 and 42) may conceivably disconnect due to the vibration stress. However, even if the braided shield lines (32 and 42) are disconnected, the ground connection function between the electric brake control unit 10 and the electric brake actuator 20 is ensured by the earth lines (35 and 45). It is also possible to suppress the influence on the signal line 41 of high frequency noise generated by the power line 31.

### Other Embodiments

The present invention is not limited to the embodiment described above with reference to the drawings, and the following embodiments are also encompassed within the technical scope of the present invention, for example.

(1) The above embodiment described an example in which the earth lines (35 and 45) are provided to both the power cable 30 and the signal cable 40, but the present invention is not limited thereto. For example, the earth line may be provided only to the power cable 30, or the earth line may be provided only to the signal cable 40, on the basis of the possibility of disconnection of the shield lines, the effect of noise reduction, and the like. In short, it is sufficient that the earth line is provided to at least one of the power cable and the signal cable.

(2) The above embodiment described an example in which the cable connection structure according to the present application is applied to an electric brake of an automobile (EMB), with the control unit as the electric brake control unit 10, and the controlled unit as the electric brake actuator 20, but the present invention is not limited thereto. For example, the cable connection structure can also be applied to an in-wheel motor of an automobile, a side mirror camera of an automobile, and the like. Furthermore, the application is not limited to a vehicle such as an automobile. In other words, the cable connection structure according to the present application can be applied to any configuration in which a ground part of a controlled unit is placed in a state apart from an ground part of a control unit, and the ground part of the control unit and the ground part of the controlled unit are connected via a shield line.

### LIST OF REFERENCE NUMERALS

1 Cable connection structure
2 Cable
10 Electric brake control unit (control unit)
15 Control-side ground
20 Electric brake actuator (controlled unit)
25 Actuator ground (controlled-side ground)
25P Power ground (controlled-side ground)
25S Signal ground (controlled-side ground)
30 Power cable
31 Power line
31A One end of power line
31B Other end of power line
32 Power shield line
32B Other end of power shield line
35 Power earth line (earth line)
40 Signal cable
41 Signal line
41A One end of signal line
41B Other end of signal line
42 Signal shield line
42A One end of signal shield line
42B Other end of signal shield line
45 Signal earth line (earth line)

1. A cable connection structure that connects a control unit and a controlled unit to each other, the cable connection structure comprising:
a cable including a power cable including a power line that supplies power and a power shield line that is formed by a braided wire and shields the power line, and a signal cable including a signal line that transmits electric signals and a signal shield line that is formed by a braided wire and shields the signal line;
a control unit that is connected to one end of the power line and one end of the signal line, includes a control-side ground, and controls supply of the power and transmission of the electric signals, and
a controlled unit that is connected to another end of the power line and another end of the signal line, includes a controlled-side ground, receives supply of power from the control unit, and exchanges the electric signals with the control unit,
wherein the power shield line is connected to the control-side ground and the controlled-side ground,
the signal shield line is connected to the control-side ground and the controlled-side ground, and
at least one of the power cable and the signal cable includes an earth line that connects the control-side ground and the controlled-side ground to each other.

2. The cable connection structure according to claim 1,
wherein both the power cable and the signal cable include the earth line.

3. The cable connection structure according to claim 1,
wherein the earth line is formed by an insulated wire, and is arranged inside the power shield line and the signal shield line.

4. The cable connection structure according to claim 2, wherein the controlled-side ground includes:
a power ground to which the other end of the power line and the earth line of the power cable are connected; and
a signal ground to which the other end of the signal line and the earth line of the signal cable are connected, and
the power ground and the signal ground are individually provided separated from each other.

5. The cable connection structure according to claim 1, wherein the control unit is an electric brake control unit that is provided inside a vehicle body of a vehicle, and controls an electric brake actuator of the vehicle, and
the controlled unit is the electric brake actuator provided outside the vehicle body of the vehicle.
